(19) United States
(12) Patent Application Publication
(10) Pub. No.: US 2007/0155109 A1
(43) Pub. Date: Jul. 5, 2007

(54) METHOD FOR FABRICATING A SEMICONDUCTOR DEVICE

(76) Inventor: Hyun Soo Shin, Chungbuk (KR)

Correspondence Address: SHERR & NOURSE, PLLC, 620 HERNDON PARKWAY, SUITE 200, HERNDON, VA, 20170, US

(21) Appl. No.: 11/617,145

(22) Filed: Dec. 28, 2006

(30) Foreign Application Priority Data
Dec. 29, 2005 (KR) 10-2005-0133457

(51) Int. Cl. H01L 21/336

(52) U.S. Cl. 438/301; 438/303; 257/346

(57) ABSTRACT

Embodiments relate to a method for fabricating a semiconductor device. In embodiments, the method may include forming a gate insulating layer and a gate on a semiconductor substrate, performing a rapid thermal process, in which a sidewall oxidation process and a gate conductance annealing process are combined as a single process, with respect to the semiconductor substrate, forming a pocket and a source/drain extension region in the semiconductor substrate, forming a spacer on both sides of the gate, and forming a deep source/drain region in the semiconductor substrate. Because the sidewall oxidation process and the gate conductance annealing process may be combined and performed as a single process, a number of the pre-cleaning processes may be reduced from two to one, and the loading/unloading time of the semiconductor substrate may also be reduced from two to one.

The present application claims priority under 35 U.S.C. 119 and 35 U.S.C. 365 to Korean Patent Application No. 10-2005-0133457(filed on Dec. 29, 2005), which is hereby incorporated by reference in its entirety.

### BACKGROUND

An isolation layer of a semiconductor device may be formed on a silicon substrate by a STI process. Wells for an N-MOS transistor and a P-MOS transistor may be formed on the silicon substrate. A gate insulating layer and a gate may be formed on an active area of the silicon substrate, and pockets and source/drains may be formed by an ion implantation process for the N-MOS transistor and the P-MOS transistor. To prevent a junction leakage, sidewall oxidation and gate conductance annealing may be performed after forming the gate insulating layer and the gate.

For example, the sidewall oxidation may be performed at a temperature of 800° C. in an O₂ atmosphere for approximately 20 seconds, as illustrated in FIG. 1, and the gate conductance annealing may be performed at a temperature of 1015° C. in N₂ atmosphere for approximately 10 seconds, as illustrated in FIG. 2.

In a related art method for fabricating a semiconductor device, the two processes of the sidewall oxidation and the gate conductance annealing may be consecutively performed. In this scenario, a pre-cleaning may need to be performed two times and the loading and unloading of the silicon substrate may also need to be performed two times. Thus, the process may result in a loss of time during manufacturing. The time loss may cause problems with respect to product yield, manufacturing cost, and price competitiveness.

### SUMMARY OF THE INVENTION

Embodiments relate to a method for fabricating a semiconductor device. Embodiments relate to a method of fabricating a semiconductor device capable of simplifying the manufacturing process for the semiconductor device.

Embodiments relate to a method for fabricating a semiconductor device that may be capable of reducing time loss.

In embodiments, in a method for fabricating a semiconductor device a sidewall oxidation process and a gate conductance anneal process may be consecutively performed in a single process.

In embodiments, the sidewall oxidation process may be performed in an O₂ atmosphere, the gate conductance annealing process may be performed in the N₂ atmosphere, and a purge process may be performed between the sidewall oxidation process and the gate conductance process.

In embodiments, a method for fabricating a semiconductor device may include forming a gate insulating layer and a gate on a semiconductor substrate, performing a rapid thermal process, in which a sidewall oxidation process and a gate conductance anneal process are combined as a single process, with respect to the semiconductor substrate, forming a pocket and a source/drain extension region in the semiconductor substrate, forming a spacer on both sides of the gate, and forming a deep source/drain region in the semiconductor substrate.

In embodiments, performing the rapid thermal process, in which a sidewall oxidation process and a gate conductance anneal process are combined as a single process, with respect to the semiconductor substrate may include performing the sidewall oxidation process at a first temperature in an O₂ atmosphere, performing a purge process at a second temperature relatively lower than the first temperature, and performing the gate conductance anneal process at a third temperature relatively higher than the first temperature in the N₂ atmosphere.

In embodiments, the step of performing the sidewall oxidation process at a first temperature in O₂ atmosphere progresses the sidewall oxidation process at a temperature of 800° Celsius for 20 seconds while supplying O₂.

The step of performing a purge process at a second temperature relatively lower than the first temperature may be performed at a temperature of 570° Celsius while supplying 20 l of N₂ per minute.

The step of performing the gate conductance annealing process at a third temperature relatively higher than the first temperature in N₂ atmosphere may include a step of performing the gate conductance anneal process at a temperature of 1015° C. for 10 seconds while supplying N₂ .

According to the present invention, because the sidewall oxidation process and the gate conductance anneal process are combined and progressed as a single process, the number of the pre-cleaning process may be reduced from two to one, and the loading/unloading times of the semiconductor substrate may be reduced from two to one.

### BRIEF DESCRIPTION OF THE DRAWINGS

FIG. 1 is an example graph illustrating a sidewall oxidation process in a related art fabricating method of a semiconductor device;

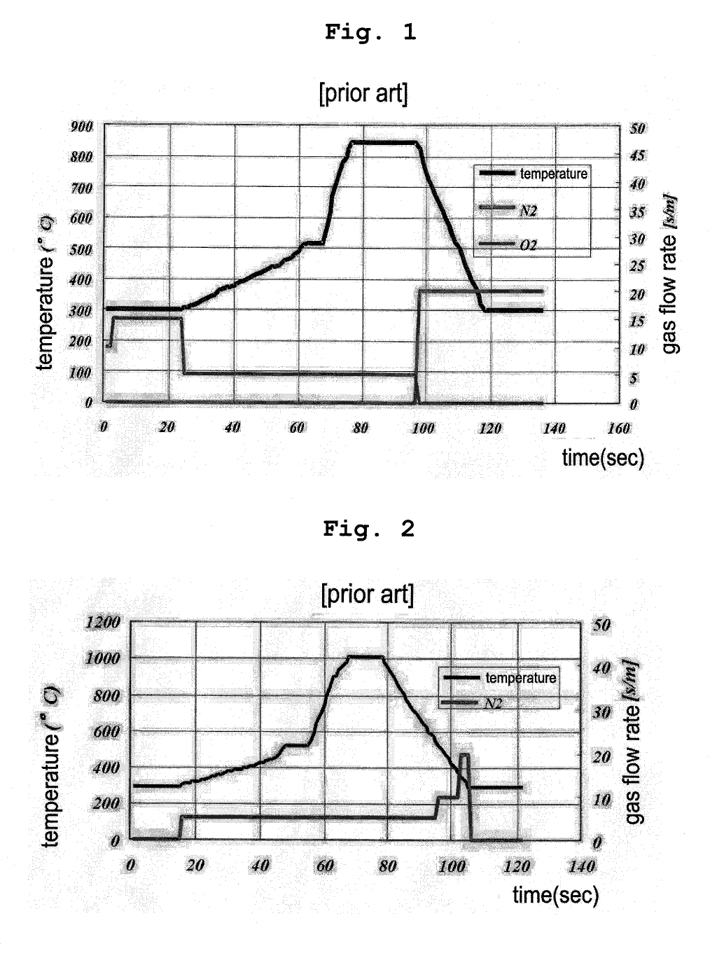

FIG. 2 is an example graph illustrating a gate conductance annealing process in a related art fabricating method of a semiconductor device;

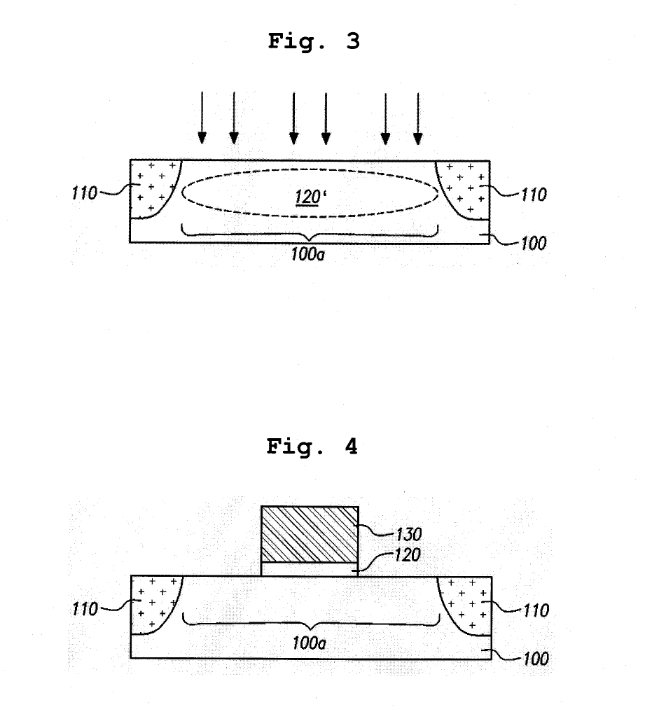

FIGS. 3 to 7 are example cross-sectional diagrams illustrating a method for fabricating a semiconductor device according to embodiments;

FIG. 8 is an example graph illustrating a rapid thermal process in a method for fabricating a semiconductor device according to embodiments;

FIG. 9 is an example graph illustrating a current-voltage characteristic of a P-MOS transistor formed by a method for fabricating a semiconductor device according to embodiments;

FIG. 10 is an example graph illustrating an off current characteristic of a P-MOS transistor formed by a method for fabricating a semiconductor device according to embodiments;

FIG. 11 is an example graph illustrating a current-voltage characteristic of an N-MOS transistor formed by a method for fabricating a semiconductor device according to embodiments; and

FIG. 12 is an example graph illustrating an off current characteristic of an N-MOS transistor formed by a method for fabricating a semiconductor device according to embodiments.

### DETALED DESCRIPTION OF EMBODIMENTS

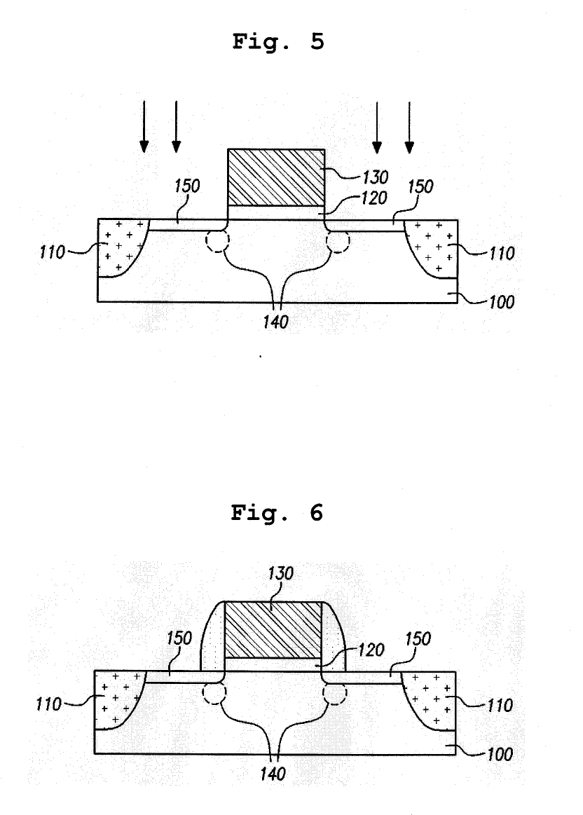

Referring to FIG. 3, isolation layers 110 may be formed in a semiconductor substrate, e.g., a silicon substrate 100. In embodiments, isolation layers 110 may be formed by a Shallow Trench Isolation (STI) process suitable for manufacturing a highly-integrated semiconductor chip. An area between isolation layers 110 in silicon substrate 100 may be called active area 100a where circuit components of a semiconductor chip, such as a gate and a source/drain, may be formed. Well 120′ may be formed by implanting appropriate ions into silicon substrate 100. In embodiments, the ions to be implanted into silicon substrate 100 may be varied depending on the type of transistor, such as an N-MOS transistor and a P-MOS transistor.

Referring to FIG. 4, gate insulating layer 120 and gate 130 may be formed on active area 100a of silicon substrate 100, for example by depositing and patterning an oxide layer and polysilicon. Two rapid thermal processes (RTPs), i.e., a sidewall oxidation process and a gate conductance annealing process, may be performed. This may prevent a junction leakage phenomenon. In embodiments, the two rapid thermal processes may be combined.

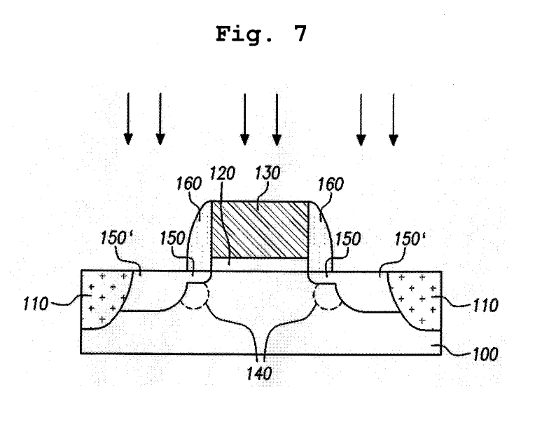

FIG. 8 is an example graph illustrating the rapid thermal process, in which the sidewall oxidation process and the gate conductance annealing process may be combined.

Referring to FIG. 8, the sidewall oxidation process may be performed at a temperature of approximately 800° C. in an O₂ atmosphere for approximately 20 seconds. A purge process may be performed by applying N₂ with a flow rate of approximately 20 l per minute while maintaining the temperature at approximately 570° C. for approximately 5 seconds. The annealing process may be performed again in the N₂ atmosphere for approximately 10 seconds at a higher temperature of approximately 1015° C. The above processes may be consecutively performed in one chamber. Such an RTP merge process may have an advantage that a thermal process may be performed within a relatively short period of time without causing problems that may otherwise occur.

Referring to FIG. 5, appropriate ions may be implanted into silicon substrate 100 where the rapid thermal process may be performed. Pocket regions 140 and source/drain extension regions 150 or LDD (lightly doped drain) regions may thus be formed. Pocket regions 140 and source/drain extension regions 150 may be formed in an effort to improve certain electrical characteristics of the semiconductor device, such as a short channel effect, a thermo-electron, a threshold voltage, and so on. In embodiments, the ions to be implanted in silicon substrate 100 may be varied depending on the type of the transistor to be manufactured, such as an N-MOS transistor or a P-MOS transistor.

Referring to FIG. 6, spacers 160 (shown in FIG. 7) may be formed on both sides of gate 130, for example by depositing and patterning of an oxide layer.

Referring to FIG. 7, in embodiments, particular ions may be implanted into silicon substrate 100 under both sides of gate 130, for example by an ion implantation process using gate 130 and the spacers 160 as masks. Deep source/drain regions 150′ may thus be formed. When forming an N-MOS transistor, an N+ source/drain ion implantation process may be performed. When forming a P-MOS transistor, a P+ source/drain ion implantation process may be performed after a Pre-Amorphous Implantation (PAT) process. A transistor may be formed on silicon substrate 100 through such a series of steps. The semiconductor device may be completed by performing subsequent processes.

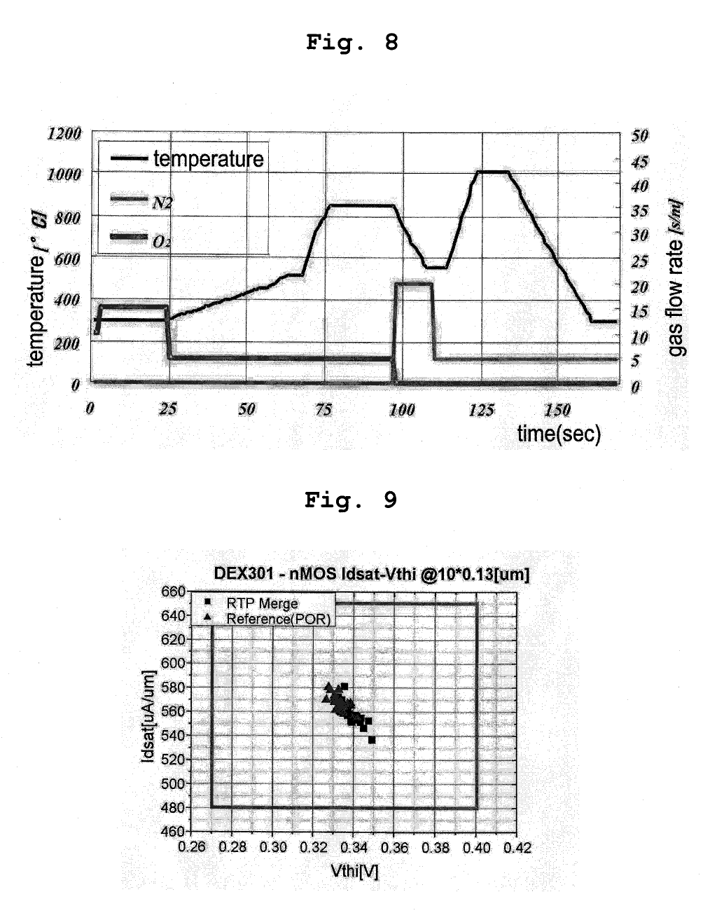

Certain electric characteristics of a transistor formed through the above processes according to embodiments are illustrated in FIGS. 9 to 12.

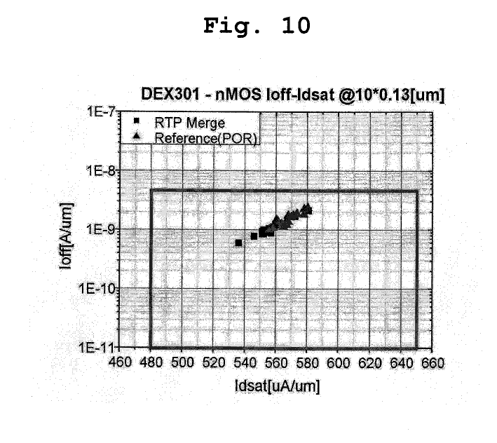

In the case of the N-MOS transistor, referring to a current (I)-voltage (V) characteristic as illustrated in FIG. 9 and an off current (Ioff) characteristic as illustrated in FIG. 10, the electric characteristics of the transistor may not be deteriorated by combining a sidewall oxidation process and a gate conductance annealing process processes into the rapid thermal process according to embodiments.

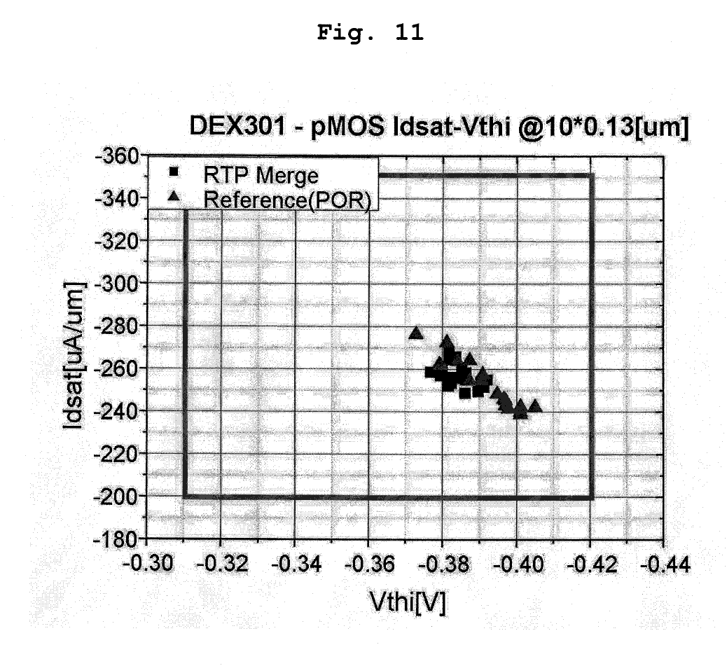

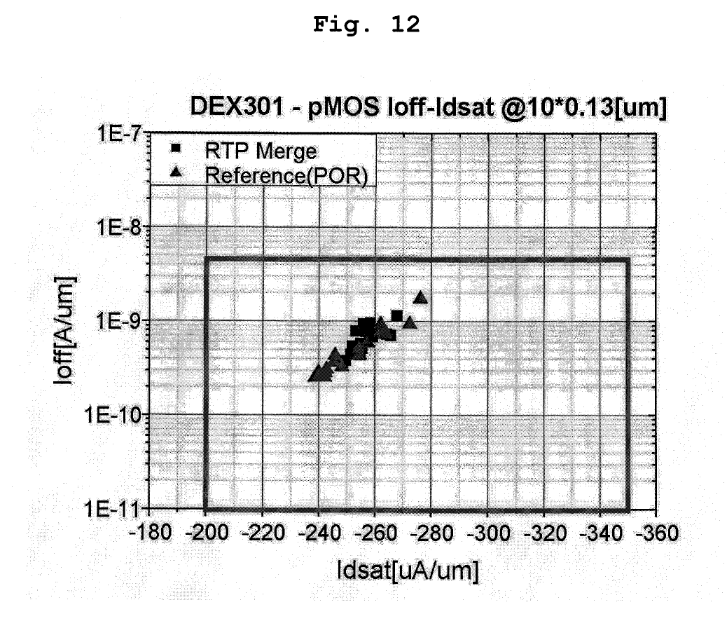

Similarly, in the case of the P-MOS transistor, as seen from a current-voltage characteristic illustrated in FIG. 11 and an off current characteristic illustrated in FIG. 12, a degradation of the transistor characteristics may not be exhibited.

According to embodiments, because a sidewall oxidation process and a gate conductance annealing process may be combined and performed as a single process, a number of the pre-cleaning processes may be reduced from two to one, and time required for loading/unloading the semiconductor substrate may be reduced from two to one. Therefore, time required for manufacturing the semiconductor device may be shortened, which may improve the product yield.

It will be apparent to those skilled in the art that various modifications and variations can be made to embodiments. Thus, it is intended that embodiments cover modifications and variations thereof within the scope of the appended claims. It is also understood that when a layer is referred to as being “on” or “over” another layer or substrate, it can be directly on the other layer or substrate, or intervening layers may also be present.

What is claimed is:

1. A method of fabricating a semiconductor device, comprising:
performing a sidewall oxidation process; and
performing a gate conductance annealing process, wherein the sidewall oxidation process and the gate conductance annealing process are consecutively performed as a single process.

2. The method of claim 1, wherein the sidewall oxidation process is performed in an O₂ atmosphere, the gate conductance anneal process is performed in an N₂ atmosphere, and a purge process is performed between the sidewall oxidation process and the gate conductance process.

3. The method of claim 2, wherein the sidewall oxidation process is performed at a temperature of 800° C. for 20 seconds while supplying O₂.

4. The method of claim 2, wherein the purge process is performed at a temperature of 570° C. while supplying N₂ of 20 l per minute.

5. The method of claim 2, wherein the gate conductance annealing process is performed at a temperature of 1015° C. for 10 seconds while supplying N₂.

6. A method comprising:
forming a gate insulating layer and a gate over a semiconductor substrate;
performing a rapid thermal process, in which a sidewall oxidation process and a gate conductance annealing process are combined and performed as a single process, with respect to the semiconductor substrate; and
forming at least one of a pocket and a source/drain region in the semiconductor substrate.

7. The method of claim 6, further comprising:
forming spacers on both sides of the gate; and
forming a deep source/drain region in the semiconductor substrate.

8. The method of claim 6, wherein performing the rapid thermal process comprises:
performing the sidewall oxidation process at a first temperature in an O₂ atmosphere;
performing a purge process at a second temperature lower than the first temperature; and
performing the gate conductance annealing process at a third temperature higher than the first temperature in an N₂ atmosphere.

9. The method of claim 8, wherein the sidewall oxidation process is performed at a temperature of 800° C. while supplying O₂.

10. The method of claim 9, wherein the sidewall oxidation process is performed for 20 seconds.

11. The method of claim 8, wherein the purge process is performed at a temperature of 570° C. while supplying N₂ of 20 l per minute.

12. The method of claim 11, wherein the purge process is performed for 5 seconds.

13. The method of claim 8, wherein the gate conductance annealing process is performed at a temperature of 1015° C. while supplying N₂.

14. The method of claim 13, wherein the gate conductance annealing process is performed for 10 seconds.

15. A device comprising:
a gate insulating layer and a gate over a semiconductor substrate;
a pocket and a source/drain extension region in the semiconductor substrate;
spacers on both sides of the gate; and
a deep source/drain region in the semiconductor substrate,
wherein a rapid thermal process is performed, in which a sidewall oxidation process and a gate conductance annealing process are combined as a single process, with respect to the semiconductor substrate.

16. The device of claim 15, wherein the sidewall oxidation process is performed at a first temperature in an O₂ atmosphere, a purge process is performed at a second temperature relatively lower than the first temperature, and the gate conductance annealing process is performed at a third temperature relatively higher than the first temperature in an N₂ atmosphere.

17. The device of claim 16, wherein the sidewall oxidation process is performed at a temperature of 800° C. for approximately 20 seconds while supplying O₂.

18. The device of claim 16, wherein the purge process is formed at a temperature of 570° C. while supplying N₂ of 20 l per minute for approximately 5 seconds.

19. The device of claim 16, wherein the gate conductance annealing process is performed at a temperature of 1015° C. for approximately 10 seconds while supplying N₂.

20. The device of claim 15, wherein the sidewall oxidation process is performed at a temperature of 800° C. for approximately 20 seconds while supplying O₂, the purge process is sequentially formed at a temperature of 570° C. while supplying N₂ of 20 l per minute for approximately 5 seconds, and the gate conductance annealing process is sequentially performed at a temperature of 1015° C. for approximately 10 seconds while supplying N₂.
